(19) United States
(12) Patent Application Publication
(10) Pub. No.: US 2024/0348076 A1
(43) Pub. Date: Oct. 17, 2024

(54) Charging method for a battery pack of an electric hand-held power tool

(71) Applicant: Hilti Aktiengesellschaft, Schaan (LI)

(72) Inventor: Robert STANGER, Kaufbeuren (DE)

(21) Appl. No.: 18/681,952

(22) PCT Filed: Aug. 26, 2022
(86) PCT No.: PCT/EP2022/073740

§ 371 Date: Feb. 7, 2024

(30) Foreign Application Priority Data
Sep. 7, 2021 (EP) 21195249.4

(51) Int. Cl. H02J 7/00; G01R 31/374; G01R 31/389

(52) U.S. Cl. CPC H02J 7/00712; H02J 7/005; G01R 31/374; G01R 31/389

(57) ABSTRACT

Battery cell charging method for charging a lithium ion battery cell of a battery pack of an electric hand-held power tool, in which a charging current made available to the lithium ion battery cell is set on the basis of a cell state characterizing the lithium ion battery cell, wherein the cell state characterizing the lithium ion battery cell is a state of health and/or an internal resistance of the lithium ion battery cell.

The present invention relates to a battery cell charging method for charging a lithium ion battery cell of a battery pack of an electric hand-held power tool. In the battery cell charging method, a charging current made available to the lithium ion battery cell is set on the basis of a cell state characterizing the lithium ion battery cell. Battery cell charging methods which are controlled on the basis of a temperature cell state of the lithium ion battery cell of a battery pack are fundamentally known from the prior art.

### BACKGROUND

EP 2 276 139 B1 describes a battery cell charging method for charging a lithium ion battery cell, wherein the battery cell charging method comprises applying a variable charging voltage and a variable current to the battery cell on the basis of a continuously variable voltage charging profile, wherein the continuously variable voltage charging profile is determined on the basis of an imaginary resistance which is in series with a resistance of a DC model of the battery cell.

U.S. Pat. No. 8,116,998 B2 discloses a method for determining a state of health of a battery cell in order to determine whether the battery cell is defective.

### SUMMARY OF THE INVENTION

It is an object of the present invention to specify a battery cell charging method for charging a lithium ion battery cell of an electric hand-held power tool, which method creates the basis for an increased service life of the lithium ion battery pack and the basis for shortening the charging time.

The present invention provides that the cell state characterizing the lithium ion battery cell is a state of health (SoH) and/or an internal resistance (DCR) of the lithium ion battery cell.

The invention includes the knowledge that temperature-based charging of a lithium ion battery pack of an electric hand-held power tool enables only inaccurate charging currents which are not matched to the state of health (SoH) of the lithium ion battery cell. As a result, the charging times for lithium ion battery cells with a good SoH are longer than necessary. In the case of lithium ion battery cells with a poor SoH, aging advances more quickly since the charging currents are possibly too high and damage the lithium ion battery cells.

It has also been recognized that the state of health (SoH) of the lithium ion battery cells can be assumed to be directly proportional to the resistance (DCR) of the lithium ion battery cell. It is therefore possible to adapt the charging current to the respective SoH after the DCR has been determined. Therefore, in the case of a lithium ion battery cell with a good state of health (this corresponds to a comparatively low internal resistance DCR), the charging current can be increased, on the one hand, which shortens the charging times. On the other hand, in the case of an aged lithium ion battery cell (this corresponds to a comparatively high internal resistance DCR), the charging current can be reduced, which slows down aging of the lithium ion battery cell and therefore increases the service life.

In one particularly preferred configuration of the method, the internal resistance of the lithium ion battery cell is measured and/or determined. For this purpose, an open-circuit voltage of the lithium ion battery cell can be measured without a load and/or an operating voltage of the lithium ion battery cell loaded with a predefined resistance.

It has been found to be advantageous if a lower charging current than the preceding charging current is set when a predetermined internal resistance threshold is exceeded. Alternatively or additionally, a higher charging current than the preceding charging current can be set when a predetermined internal resistance threshold is undershot. It has been found to be advantageous if at least two, preferably three, internal resistance thresholds are provided.

In one particularly preferred configuration of the method, the charging current is set in discrete steps, preferably solely in discrete steps. It has been found to be advantageous if at least three, preferably four, discrete and mutually different charging currents are provided. In a further particularly preferred configuration, the internal resistance determined at the end of a respective charging process is stored.

In one particularly preferred configuration of the method, the battery pack may have a plurality of lithium ion battery cells. It has been found to be advantageous if the charging current provided is set on the basis of an averaged internal resistance of the plurality of lithium ion battery cells. It has likewise been found to be advantageous if an open-circuit voltage (DC voltage) of the battery pack is less than 60 volts and is preferably 12 volts, 22 volts or 36 volts.

In a further preferred configuration, provision may be made for the internal resistance of the lithium ion battery cell to be weighted with a temperature cell state of the lithium ion battery cell, in particular before a charging current is determined. The internal resistance can therefore be multiplied by a reciprocal of the cell temperature (or a multiple of the reciprocal), for example. The reciprocal can be discretized. It is conceivable to predefine the charging current by means of a lookup table. In another particularly preferred configuration of the method, a temperature cell state of the lithium ion battery cell is used only for an emergency shutdown of the charging process.

The present invention also provides a battery cell charging system for charging a lithium ion battery cell of a battery pack of an electric hand-held power tool, wherein the battery cell charging system has a charging controller which is configured to set a charging current made available to the lithium ion battery cell on the basis of a cell state characterizing the lithium ion battery cell. The cell state characterizing the lithium ion battery cell is a state of health and/or an internal resistance of the lithium ion battery cell. It has been found to be advantageous if the charging controller is arranged in the battery pack. Alternatively, the charging controller may be included in a charging station of the battery cell charging system. The battery cell charging system can be accordingly developed by means of the features used with respect to the battery cell charging method.

### BRIEF DESCRIPTION OF THE DRAWINGS

Further advantages will become apparent from the following description of the figures. Particularly preferred exemplary embodiments of the present invention are illustrated in the figures. The figures, the description and the claims contain numerous features in combination. A person skilled in the art will expediently also consider the features individually and combine them to form useful further combinations.

Identical and similar components are denoted by the same reference signs in the figures, in which:

FIG. 1 shows a preferred exemplary embodiment of a battery cell charging method; and

FIG. 2 shows a preferred exemplary embodiment of a battery cell charging system.

### DETAILED DESCRIPTION

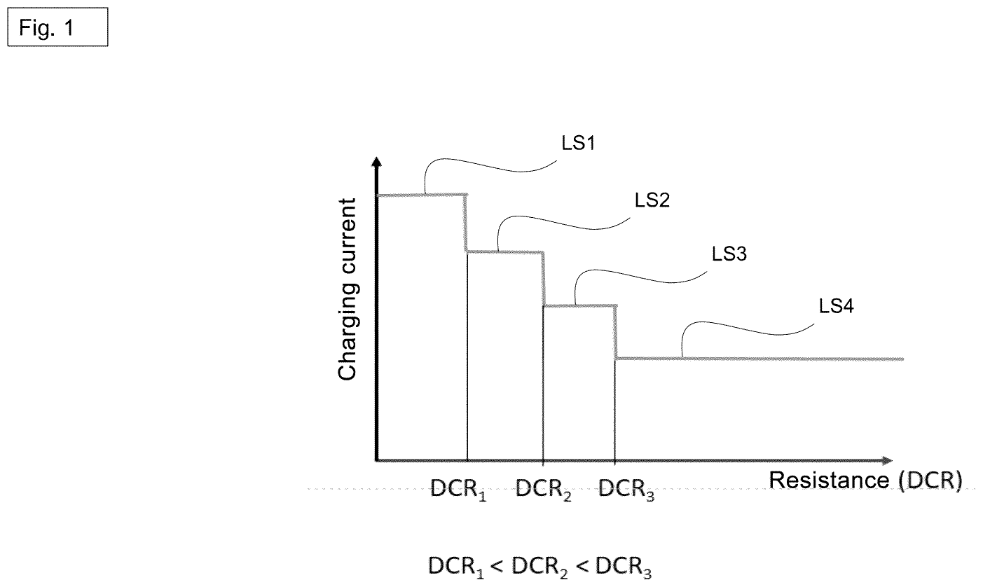

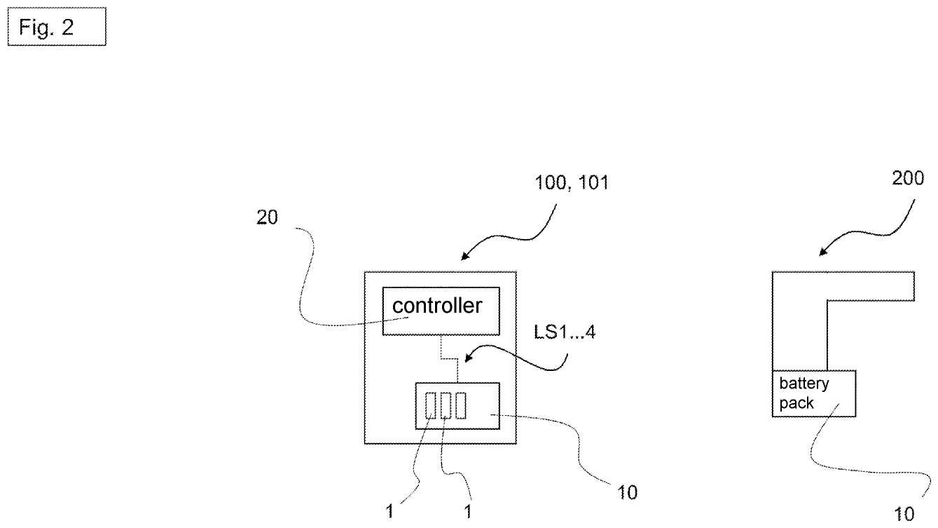

A preferred exemplary embodiment of a battery cell charging method is intended to be explained with reference to the schematic diagrammatic form shown in FIG. 1. The battery cell charging method is preferably used to charge a lithium ion battery cell of a battery pack 10 (cf. FIG. 2) of an electric hand-held power tool. In the diagram in FIG. 1, the charging current supplied to the lithium ion battery cell (ordinate) is plotted against the instantaneous internal resistance of the lithium ion battery cell DCR (abscissa).

Within the scope of the method according to the invention, provision is made for the charging current made available to the lithium ion battery cell to be set on the basis of the internal resistance DCR (which represents the state of health SoH). The internal resistance DCR of the lithium ion battery cell is measured during the method. This can be carried out continuously or at the start of a respective charging process. Alternatively or additionally, the internal resistance DCR can be read from a memory. Provision is advantageously made for the internal resistance determined at the end of a respective charging process to be stored.

In the healthy new state, the lithium ion battery cell 1 (cf. FIG. 2) has, for example, an internal resistance DCR below a first internal resistance threshold DCR1. The first internal resistance threshold DCR1 is 0.1 ohms, for example. The lithium ion battery cell is charged with a first charging current LS1. The first charging current LS1 is a constant 4 amperes, for example.

After a plurality of charging processes, the lithium ion battery cell may have, for example, an internal resistance DCR which is between the first internal resistance threshold DCR1 and a second internal resistance threshold DCR2. The second internal resistance threshold DCR2 is 0.2 ohms, for example. The lithium ion battery cell has therefore aged. The lithium ion battery cell is now charged with a second charging current LS2. The second charging current LS2 is lower than the first charging current LS1 and is a constant 3 amperes, for example.

After further charging processes, the lithium ion battery cell may have, for example, an internal resistance DCR which is between the second internal resistance threshold DCR2 and a third internal resistance threshold DCR3. The third internal resistance threshold DCR3 is 0.3 ohms, for example. The lithium ion battery cell is now charged with a third charging current LS3. The third charging current LS3 is lower than the second charging current LS2 and is a constant 2 amperes, for example.

Close to the end of its service life, the lithium ion battery cell may have, for example, an internal resistance DCR which is above the third internal resistance threshold DCR3. In this case, the lithium ion battery cell is charged from now on with a fourth charging current LS4 which is a constant 1 ampere, for example. The situation just described illustrates the fact that a low charging current is set in each case in discrete steps (for example of 1 ampere each) when a predetermined internal resistance threshold is exceeded.

It is conceivable, in principle, for the internal resistance DCR of the lithium ion battery cell to increase on account of self-organization processes inside the lithium ion battery cell. For this situation, provision may be made for a higher charging current to be set when a predetermined internal resistance threshold is undershot.

FIG. 2 shows—in a highly schematic form—a preferred exemplary embodiment of a battery cell charging system 100. The battery cell charging system 100 is used to charge a lithium ion battery cell 1 of a battery pack 10 of an electric hand-held power tool 200. The battery cell charging system 100 has a charging controller 20 which is configured to set a charging current LS1 . . . 4 made available to the lithium ion battery cell 1 on the basis of a cell state characterizing the lithium ion battery cell 1, specifically an internal resistance DCR of the lithium ion battery cell 1. In this respect, the charging controller 20 is configured to carry out the battery cell charging method described with reference to FIG. 1.

The charging controller 20 is included, for example, in a charging station 101 which, in the present case, forms the battery cell charging system 100.

### LIST OF REFERENCE SIGNS

1 Lithium ion battery cell
10 Battery pack
20 Controller
100 Battery cell charging system
101 Charging station
200 Electric hand-held power tool
SoH State of health
DCR Internal resistance
DCR1 First internal resistance threshold
DCR2 Second internal resistance threshold
DCR3 Third internal resistance threshold
LS1 First charging current
LS2 Second charging current
LS3 Third charging current
LS4 Fourth charging current

1-11. (canceled)

12: A battery cell charging method for charging a lithium ion battery cell of a battery pack of an electric hand-held power tool, the method comprising:
making available a charging current to the lithium ion battery cell, the charging current being set on the basis of a cell state characterizing the lithium ion battery cell, the cell state characterizing the lithium ion battery cell being a state of health or an internal resistance of the lithium ion battery cell.

13: The battery cell charging method as recited in claim 12 wherein the internal resistance of the lithium ion battery cell is measured during the making available step.

14: The battery cell charging method as recited in claim 12 wherein a lower charging current is set when a predetermined internal resistance threshold is exceeded.

15: The battery cell charging method as recited in claim 12 wherein a higher charging current is set when a predetermined internal resistance threshold is undershot.

16: The battery cell charging method as recited in claim 12 wherein the charging current is set solely in discrete steps.

17: The battery cell charging method as recited in claim 12 wherein the internal resistance is determined at the end of a respective charging process and stored.

18: The battery cell charging method as recited in claim 12 wherein the battery pack has a plurality of lithium ion battery cells, the charging current provided being set on the basis of an averaged internal resistance of the plurality of lithium ion battery cells.

19: The battery cell charging method as recited in claim 12 wherein the internal resistance of the lithium ion battery cell is weighted with a temperature cell state of the lithium ion battery cell.

20: The battery cell charging method as recited in claim 12 wherein a temperature cell state of the lithium ion battery cell is used only for an emergency shutdown of the charging process.

21: A battery cell charging system for charging a lithium ion battery cell of a battery pack of an electric hand-held power tool, the battery cell charging system comprising:
a charging controller configured to set a charging current made available to the lithium ion battery cell on the basis of a cell state characterizing the lithium ion battery cell, the cell state characterizing the lithium ion battery cell being a state of health or an internal resistance of the lithium ion battery cell.

22: The battery cell charging system as recited in claim 21 wherein the charging controller is arranged in the battery pack or is included in a charging station of the battery cell charging system.
